(19) United States
(12) Patent Application Publication
(10) Pub. No.: US 2014/0231958 A1
(43) Pub. Date: Aug. 21, 2014

(54) CAPACITORS HAVING DIELECTRIC LAYERS WITH DIFFERENT BAND GAPS AND SEMICONDUCTOR DEVICES USING THE SAME

(71) Applicant: Samsung Electronics Co., Ltd., Suwon-si (KR)

(72) Inventors: Han-Jin Lim, Seoul (KR); Seok-Woo Nam, Seongnam-si (KR); Jung-Hwan Oh, Yongin-si (KR); Ki-Vin Im, Seongnam-si (KR)

(73) Assignee: Samsung Electronics Co., Ltd., Suwon-si (KR)

(21) Appl. No.: 14/070,988

(22) Filed: Nov. 4, 2013

(30) Foreign Application Priority Data
Feb. 18, 2013 (KR) 10-2013-0017066

(51) Int. Cl. H01L 49/02

(52) U.S. Cl. CPC H01L 28/40
USPC 257/532

(57) ABSTRACT

A capacitor of a memory device includes dielectric layers with different energy band gaps. The capacitor may include, for example, a first electrode and a first dielectric layer on the first electrode. The capacitor may further include a second dielectric layer on the first dielectric layer. The first and second dielectric layers may include the same dielectric material with different concentration of an impurity therein. A second electrode is disposed on the second dielectric layer.

### CROSS-REFERENCE TO RELATED APPLICATION

This application claims priority and all the benefits accruing therefrom under 35 U.S.C. 119 from Korean Patent Application No. 10-2013-0017066 filed on Feb. 18, 2013 in the Korean Intellectual Property Office, the content of which is herein incorporated by reference in its entirety.

### BACKGROUND

1. Field of the Invention

The inventive subject matter relates to memory devices and, more particularly, to capacitors for semiconductor devices and semiconductor devices using the same.

2. Description of the Related Art

Recent trends toward large-capacity and highly integrated semiconductor devices have been accompanied by decreasing design rules. Such trends apply to dynamic random access memory (DRAM). In order for a DRAM to operate reliably, capacitance exceeding a predetermined level is typically required for each cell. An increase in the capacitance may increase an amount of charge stored in a capacitor, thereby improving a refresh characteristic of a semiconductor device. The improved refresh characteristic of the semiconductor device may increase fabrication yield. Reduction in leakage current in a semiconductor memory device typically reduces the loss of charge stored in capacitors, which can increase the reliability of the semiconductor device.

### SUMMARY

Some embodiments of the inventive subject matter provide a capacitor including a first electrode and a first dielectric layer on the first electrode. The capacitor further includes a second dielectric layer on the first dielectric layer. The first and second dielectric layers include the same dielectric material with different concentration of an impurity therein. A second electrode is disposed on the second dielectric layer. The first dielectric layer may have a greater energy band gap than the second dielectric layer.

In some embodiments, the first dielectric layer may have a greater concentration of an energy band gap increasing impurity than the second dielectric layer. The energy band gap increasing impurity may include, for example, at least one of silicon (Si), aluminum (Al), hafnium (Hf) and zirconium (Zr). In some embodiments, the second dielectric layer may be undoped with the energy band gap increasing impurity.

In further embodiments, the second dielectric layer may have a greater concentration of an energy band gap decreasing impurity than the first dielectric layer. The energy band gap decreasing impurity may include, for example, at least one of titanium (Ti), tantalum (Ta) and strontium (Sr). In some embodiments, the first dielectric layer may be undoped with the energy band gap decreasing impurity.

Some embodiments of the inventive subject matter provide a capacitor including a first electrode, a first dielectric layer on the first electrode and including a first impurity, a second dielectric layer on the first dielectric layer and including a second impurity different from the first impurity, and a second electrode formed on the second dielectric layer. The first dielectric layer and the second dielectric layer may include the same dielectric material. The first impurity may increase an energy band gap of the first dielectric layer and the second impurity may decrease an energy band gap of the second dielectric layer. The first impurity may include, for example, at least one of silicon (Si), aluminum (Al), hafnium (Hf) and zirconium (Zr), and the second impurity may include, for example, at least one of titanium (Ti), tantalum (Ta) and strontium (Sr).

In some embodiments, the first dielectric layer may have a first energy band gap and the second dielectric layer may have a second energy band gap. The first energy band gap may be greater than the second energy band gap. In some embodiments, the first impurity may increase the energy band gap of the first dielectric layer, and the second impurity may decrease the energy band gap of the second dielectric layer.

Still further embodiments of the inventive subject matter provide a memory device including a substrate and a plurality of memory cells on the substrate. Each of the memory cells includes a data storage capacitor including multiple dielectric layers with different energy band gaps.

In some embodiments, each data storage capacitor may include a first electrode, a first dielectric layer on the first electrode, a second dielectric layer on the first dielectric layer including the same dielectric material as the first dielectric layer and a different concentration of an impurity than the first dielectric layer, and a second electrode on the second dielectric layer. In further embodiments, each data storage capacitor may include a first electrode, a first dielectric layer on the first electrode and including a first impurity, a second dielectric layer on the first dielectric layer and including a second impurity different from the first impurity, and a second electrode formed on the second dielectric layer.

### BRIEF DESCRIPTION OF THE DRAWINGS

The above and other features and advantages of the inventive subject matter will become more apparent by describing in detail preferred embodiments thereof with reference to the attached drawings in which:

FIG. 1 is a layout view of a semiconductor device without a capacitor according to some embodiments of the inventive subject matter;

FIG. 2 is a cross-sectional view taken along the line AA of FIG. 1, illustrating a semiconductor device with a capacitor according to some embodiments of the inventive subject matter;

FIG. 3 is a cross-sectional view illustrating a capacitor according to first embodiments of the inventive subject matter;

FIG. 4 is a cross-sectional view illustrating a capacitor according to second embodiments of the inventive subject matter;

FIG. 5 is a cross-sectional view illustrating a capacitor according to third embodiments of the inventive subject matter;

FIG. 6 is a cross-sectional view illustrating a capacitor according to fourth embodiments of the inventive subject matter;

FIG. 7 is a cross-sectional view illustrating a capacitor according to fifth embodiments of the inventive subject matter;

FIG. 8 is a cross-sectional view illustrating a capacitor according to sixth embodiments of the inventive subject matter;

FIG. 9 illustrates I-V characteristic curves of capacitors according to some embodiments of the inventive subject matter;

FIGS. 10A to 12B are diagrams illustrating changes in the energy band diagrams according to the voltages applied to the capacitors according to some embodiments of the inventive subject matter;

FIG. 13 is a block diagram illustrating an exemplary electronic system including semiconductor devices having capacitors according to some embodiments of the inventive subject matter; and

FIG. 14 is a block diagram illustrating an exemplary memory card including semiconductor devices having capacitors according to some embodiments of the inventive subject matter.

### DETAILED DESCRIPTION

The inventive subject matter will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification. In the attached figures, the thickness of layers and regions is exaggerated for clarity.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. Like numbers refer to like elements throughout. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the inventive subject matter,

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified. Further, unless defined otherwise, all terms defined in generally used dictionaries may not be overly interpreted.

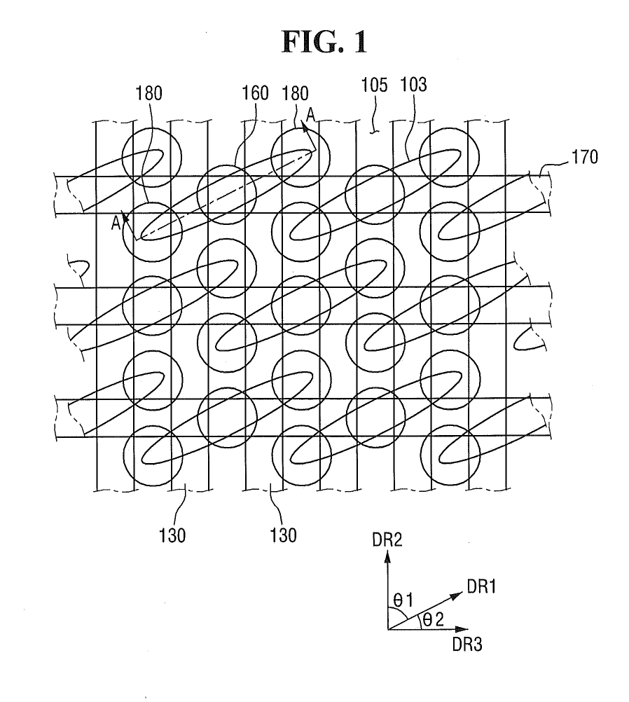

Hereinafter, a semiconductor device according to some embodiments of the inventive subject matter will be described with reference to FIG. 1.

FIG. 1 is a layout view of a semiconductor device prior to formation of a capacitor according to some embodiments of the inventive subject matter. Referring to FIG. 1, in the semiconductor device according to some embodiments of the inventive subject matter, a unit active region 103 is defined by forming an isolation region 105 in a substrate 100. The unit active region 103 extends in a first direction DR1, a gate electrode (i.e., a word line) 130 extends in a second direction DR2, which forms an acute angle with respect to the first direction DR1, and a bit line 170 extends in a third direction D3, which forms an acute angle with respect to the first direction DR1.

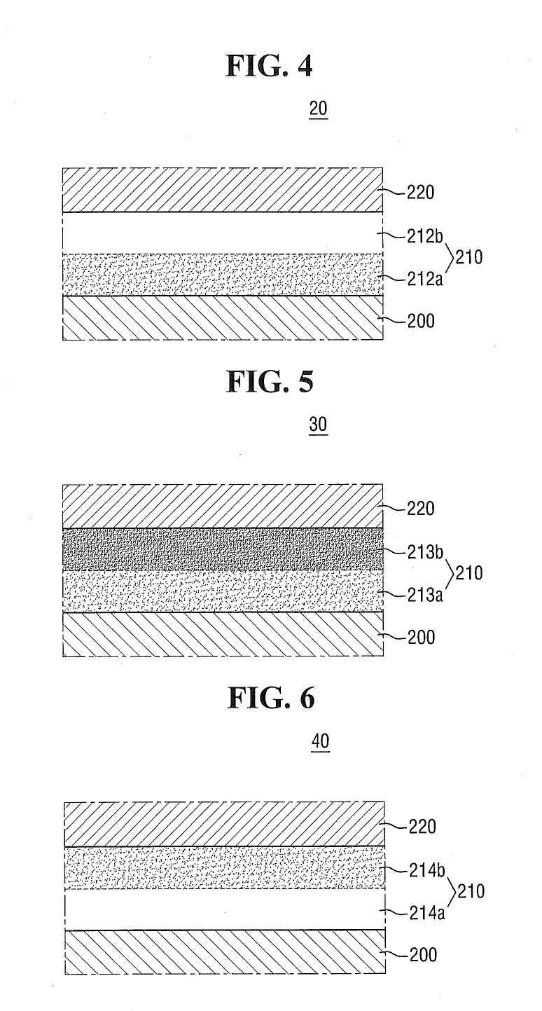

Here, the term “angle” used in the phrase “a predetermined angle formed between a particular direction and another particular direction” may mean a smaller angle of two angles formed when two directions cross each other, for example, 60° in a case where angles formed by two crossing directions are 120° and 60°. Therefore, as shown in FIG. 4, an angle formed by the first direction DR1 and the second direction DR2 is θ1, and an angle formed by the first direction DR1 and the third direction DR3 is θ2.

As described above, θ1 and/or θ2 are established as acute angles for the purpose of securing the maximum distance between a bit line contact 160 connecting the unit active region 103 and the bit line 170, and a storage node contact 180 (i.e., a second contact plug of FIG. 5) connecting the unit active region 103 and the capacitor. For example, θ1 and θ2 may be 45° and 45°, 30° and 60°, or 60° and 30°, respectively, but embodiments of the inventive subject matter are not limited thereto.

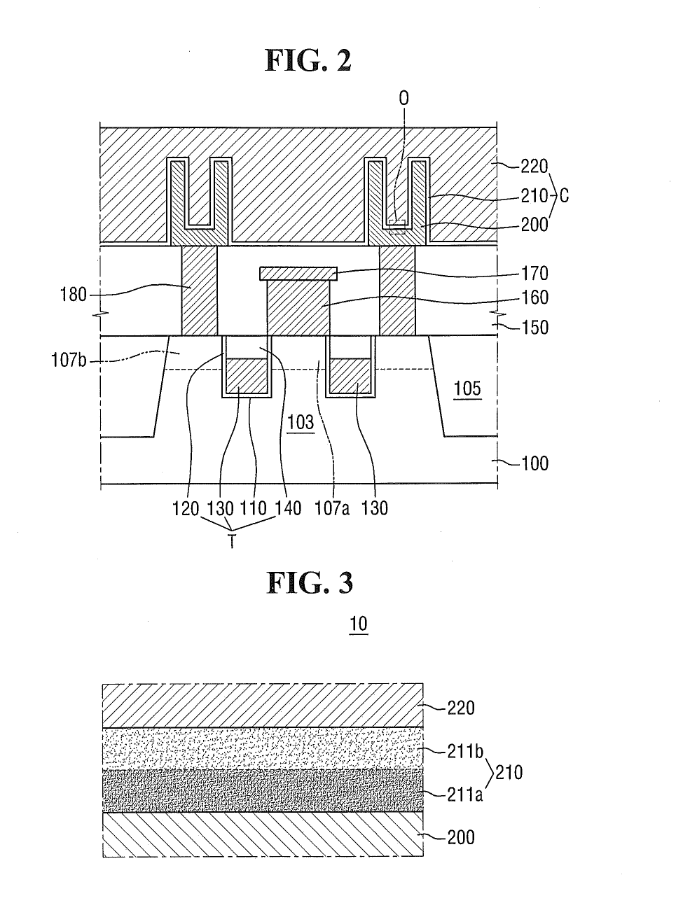

Next, a semiconductor device according to some embodiments of the inventive subject matter will be described with reference to FIG. 2.

FIG. 2 is a cross-sectional view taken along the line AA of FIG. 1, illustrating a semiconductor device with a capacitor according to some embodiments of the inventive subject matter. FIG. 2 illustrates a cross section of the semiconductor device viewed along the line AA of FIG. 1.

Referring to FIG, 2, the semiconductor device includes a substrate 100, a transistor T, a bit line 170 and a capacitor C.

A unit active region 103 and an isolation region 105 are formed on a substrate 100. The substrate 100 may have a stacked structure having a base substrate and an epitaxial layer stacked, but not limited thereto. The substrate 100 may be a silicon substrate, a gallium arsenide substrate, a silicon germanium substrate, a ceramic substrate, a quartz substrate, or a glass substrate for display. In some embodiments, the substrate 100 may be a semiconductor on insulator (SOI). In the following description, a silicon substrate is exemplified. The isolation region 105 may be formed by a shallow trench isolation (STI) process. In FIG. 1, the unit active region 103 extending in the first direction DR1 may be defined by the isolation region 105.

Two transistors T may be formed in one unit active region 103. The two transistors T may include two gate electrodes 130 formed to cross the unit active region 103, a first impurity region 107a formed in the unit active region 103 between the two gate electrodes 130, and a second impurity region 107b formed between each of the gate electrodes 130 and the isolation region 105. The two transistors T share the first impurity region 107a while not sharing the second impurity region 107b.

Each of the two transistors T may include a gate insulation layer 120, a gate electrode 130 and a capping pattern 140.

The gate insulation layer 120 may be formed along lateral surfaces and bottom surface of a trench 110 formed in the substrate 100. The gate insulation layer 120 may include, for example, silicon oxide or a high-k dielectric having a higher dielectric constant than silicon oxide. In FIG. 2, the gate insulation layer 120 is entirely formed on the side surfaces of the trench 110, but embodiments of the inventive subject matter are not limited thereto. The gate insulation layer 120 is formed to be in contact with lower portions of the side surfaces of the trench 110, and the capping pattern 140 to be described later may be formed to be in contact with upper portions of the side surfaces of the trench 110.

The gate electrode 130 may be formed to fill a portion of the trench 110, rather than completely filling the trench 110. The gate electrode 130 may be recessed. The gate electrode 130 may be formed using, for example, doped polysilicon, titanium nitride (TiN), tantalum nitride (TaN), tungsten nitride (WN), titanium (Ti), tantalum (Ta), or tungsten (W), but not limited thereto. The capping pattern 140 may be formed on the gate electrode 130 to fill the trench 110. The capping pattern 140 may be made of an insulating material, and may include, for example, at least one of silicon oxide, silicon nitride and silicon oxynitride. In FIG. 2, the capping pattern 140 fills a portion between the gate electrode 130 and the gate insulation layer 120 formed on sidewalls of the trench 110, but embodiments of the inventive subject matter are not limited thereto. The capping pattern 140 may be formed in contact with the substrate 100, i.e., with the first impurity region 107a and the second impurity region 107b.

In a semiconductor device according to to some embodiments of the inventive subject matter, the transistor T is a buried channel array transistor (BCAT), but embodiments of the inventive subject matter are not limited thereto. The transistor T may have various structures including a planar transistor or a pillar-shaped vertical channel array transistor (VCAT).

An interlayer dielectric layer 150 may be formed on the substrate 100. The interlayer dielectric layer 150 may include, for example, at least one of silicon oxide, silicon nitride and silicon oxynitride. The interlayer dielectric layer 150 may be formed of a single layer or multiple layers.

A first contact plug (bit line contact) 160 electrically connected to the first impurity region 107a may be formed in the interlayer dielectric layer 150. The first contact plug 160 may be made of a conductive material, and may include, for example, at least one of polysilicon, a metal silicide compound and a metal, but embodiments of the inventive subject matter are not limited thereto. A bit line 170 electrically connected to the first impurity region 107a may be formed on the first contact plug 160 through the first contact plug 160. The bit line 170 may be made of a conductive material, and may include, for example, at least one of polysilicon, a metal silicide compound, a conductive metal nitride and a metal, but embodiments of the inventive subject matter are not limited thereto.

A second contact plug 180 may be formed in the interlayer dielectric layer 150 while passing through the interlayer dielectric layer 150. The second contact plug 180 may be electrically connected to a second impurity region 107b. The second contact plug 180 may include a storage node contact. The second contact plug 180 may be made of a conductive material, and may include, for example, at least one of polysilicon, a metal silicide compound, a conductive metal nitride and a metal, but embodiments of the inventive subject matter are not limited thereto.

The capacitor C electrically connected to the second impurity region 107b may be formed on the interlayer dielectric layer 150. The capacitor C may be electrically connected to the second impurity region 107b through the second contact plug 180.

The capacitor C may include a lower electrode 200, a capacitor dielectric layer 210, a capacitor interface layer 220 and an upper electrode 230.

The capacitor C may include a lower electrode 200, a capacitor dielectric layer 210, and an upper electrode 220 and will later be described in more detail with reference to FIGS. 3 to 8.

In a semiconductor device according to some embodiments of the inventive subject matter, the lower electrode 200 may be shaped of a cylinder, which is provided only for illustration, but embodiments of the inventive subject matter are not limited thereto. The lower electrode 200 of the capacitor C may have a pillar shape.

A capacitor according to first embodiments of the inventive subject matter will now be described with reference to FIG. 3.

FIG. 3 is a cross-sectional view illustrating a capacitor according to first embodiments of the inventive subject matter. Specifically, FIG. 3 is an enlarged view of a portion O of FIG. 2.

Referring to FIG. 3, the capacitor 10 includes a first electrode 200, a second electrode 220 and a capacitor dielectric layer 210. The capacitor dielectric layer 210 includes a lower dielectric layer 211a and an upper dielectric layer 211b.

The first electrode 200 may include at least one selected from the group consisting of doped polysilicon, a conductive metal nitride, such as titanium nitride (TiN), tantalum nitride (TaN), or tungsten nitride (WN), a metal such as ruthenium (Ru), iridium (Ir), titanium (Ti), or tantalum (Ta), and a conductive metal oxide, such as iridium oxide. In a capacitor according to some embodiments of the inventive subject matter, the first electrode 200 may be the lower electrode 200 shown in FIG, 2. Thus, the first electrode 200 may be an electrode electrically connected to the second impurity region 107b.

The second electrode 220 is formed on the capacitor dielectric layer 210. In detail, the second electrode 220 is formed on the upper dielectric layer 211b of the capacitor dielectric layer 210. The second electrode 220 may include, for example, at least one of doped polysilicon, a conductive metal nitride, and metal silicide. In a capacitor according to some embodiments of the inventive subject matter, the second electrode 220 may be the upper electrode 220 shown in FIG. 2.

The capacitor dielectric layer 210 is interposed between the first electrode 200 and the second electrode 220. The lower dielectric layer 211a and the upper dielectric layer 211b are sequentially formed on the first electrode 200, and the second electrode 220 is formed on the upper dielectric layer 211b. In detail, the lower dielectric layer 211 a may be formed to be in contact with the first electrode 200, and the upper dielectric layer 211b may be formed to be in contact with the second electrode 220. The upper dielectric layer 211b and the lower dielectric layer 211a may also be formed to be in contact with each other.

In a capacitor according to the first embodiments of the inventive subject matter, the lower dielectric layer 211a and the upper dielectric layer 211b may be made of the same dielectric material. The lower dielectric layer 211a and the upper dielectric layer 211b may be made of the same matrix material. When impurity is not doped, the lower dielectric layer 211a and the upper dielectric layer 211b may have substantially the same energy band gap. In addition, the lower dielectric layer 211a and the upper dielectric layer 211b may include the same material, i.e., the first impurity. However, the first impurity is included in the lower dielectric layer 211a and the upper dielectric layer 211b in different concentrations. The lower dielectric layer 211a and the upper dielectric layer 211b have different impurity concentrations.

The lower dielectric layer 211a and the upper dielectric layer 211b may include one of lanthanum oxide (La₂O₃), cerium oxide (CeO₂), praseodymium oxide (Pr₆O₁₁), neodymium oxide (Nd₂O₃), promethium oxide (Pm₂O₃), samarium oxide, europium oxide (Eu₂O₃), gadolinium oxide (Gd₂O₃), terbium oxide (Tb₄O₇), dysprosium oxide (Dy₂O₃), holmium oxide (Ho₂O₃), erbium oxide (Er₂O₃), thulium oxide (Tm₂O₃), ytterbium oxide, lutetium oxide (Lu₂O₃), hafnium oxide (HfO2) and zirconium oxide (ZrO2), but not limited thereto. The lower dielectric layer 211a and the upper dielectric layer 211b may include an oxide of a lanthanide-series element, hafnium and zirconium. The lower dielectric layer 211a and the upper dielectric layer 211b may include nitride or oxynitride of a lanthanide-series element, hafnium and zirconium.

The first impurity included in the upper dielectric layer 211b and the lower dielectric layer 211a may be a material increasing energy band gaps of the upper dielectric layer 211b and the lower dielectric layer 211a. The first impurity may include, for example, at least one of silicon (Si), aluminum (Al), hafnium (Hf) and zirconium (Zr), but not limited thereto. The first impurity may be any material that is doped into interstitial sites, of the upper dielectric layer 211b and the lower dielectric layer 211a and increases the energy band gaps of the upper dielectric layer 211b and the lower dielectric layer 211a. If the first impurity is doped into substitutial sites, not interstitial sites, of the upper dielectric layer 211b and the lower dielectric layer 211a, the upper dielectric layer 211b and the lower dielectric layer 211a may have new crystal structures by the first impurity.

In a capacitor according to the first embodiments of the inventive subject matter, a concentration of the first impurity included in the lower dielectric layer 211a may be a first impurity concentration, and a concentration of the first impurity included in the upper dielectric layer 211b may be a second impurity concentration. In a capacitor according to the first embodiments of the inventive subject matter, the first impurity concentration, i.e., the impurity concentration of the lower dielectric layer 211a, is greater than the second impurity concentration, i.e., the impurity concentration of the upper dielectric layer 211b.

Since a larger amount of the first impurity increasing the energy band gap is included in the lower dielectric layer 211a than in the upper dielectric layer 211b, the energy band gap of the lower dielectric layer 211a including the first impurity of the first impurity concentration is greater than that of the upper dielectric layer 211b including the first impurity of the second impurity concentration. The energy band gaps of both of the upper dielectric layer 211b and the lower dielectric layer 211a increase, but the energy band gap of the lower dielectric layer 211a increases in a greater extent than that of the upper dielectric layer 211b.

The upper dielectric layer 211b and the lower dielectric layer 211a may be made of oxides. In a capacitor according to the first embodiments of the inventive subject matter, the upper dielectric layer 211b and the lower dielectric layer 211a may have a chemical formula MOₓ: D₁, where M is one of a lanthanide-series element, hafnium and zirconium, and D₁ may be one of first impurity elements, including silicon (Si), aluminum (Al), hafnium (Hf) and zirconium (Zr). Since the first impurity is doped into the upper dielectric layer 211b and the lower dielectric layer 211a, M and D₁ should be different materials. When M is a lanthanide-series element, the first impurity D₁ may be one of silicon (Si), aluminum (Al), hafnium (Hf) and zirconium (Zr). However, when M is one of hafnium (Hf) and zirconium (Zr), the first impurity D₁ may be one of silicon (Si) and aluminum (Al) so as not to be the same material as M, i.e., hafnium (Hf) or zirconium (Zr).

A capacitor according to second embodiments of the inventive subject matter will now be described with reference to FIG. 4. These embodiments are substantially the same as the first embodiments, except that impurity is doped into only a lower dielectric layer, the same components as those of the first embodiments are denoted by the same reference numerals, and repeated descriptions thereof will be briefly made or will be omitted. FIG. 4 is a cross-sectional view illustrating a capacitor according to second embodiments of the inventive subject matter. Specifically, FIG. 4 is an enlarged view of a portion O of FIG. 2.

Referring to FIG. 4, the capacitor 20 includes a first electrode 200, a second electrode 220 and a capacitor dielectric layer 210. The capacitor dielectric layer 210 includes a lower dielectric layer 212a and an upper dielectric layer 212b. In a capacitor according to the second embodiments of the inventive subject matter, the lower dielectric layer 212a and the upper dielectric layer 212b may be made of the same dielectric material. A first impurity is included in the lower dielectric layer 212a. However, no impurity may be included in the upper dielectric layer 212b, so that an impurity concentration of the upper dielectric layer 212b may be substantially 0. The upper dielectric layer 212b may be an undoped dielectric layer. Here, the phrase “substantially 0” used herein means that the upper dielectric layer 212b is not intentionally doped with the first impurity, suggesting that a small amount of the first impurity may be included in the upper dielectric layer 212b due to diffusion of the first impurity. As the result, the lower dielectric layer 212a and the upper dielectric layer 212b may have different impurity concentrations.

The lower dielectric layer 212a and the upper dielectric layer 212b may include one oxide of a lanthanum-series element, hafnium and zirconium. In some embodiments, the lower dielectric layer 212a and the upper dielectric layer 212b may include one nitride or oxynitride of a lanthanum-series element, hafnium and zirconium.

The first impurity included in the lower dielectric layer 212a may increase the energy band gap of the lower dielectric layer 212a. The first impurity may include, for example, at least one of silicon (Si), aluminum (Al), hafnium (Hf) and zirconium (Zr), but not limited thereto.

Since the lower dielectric layer 212a includes the first impurity increasing its energy band gap, the energy band gap of the lower dielectric layer 212a including the first impurity is greater than that of the upper dielectric layer 212b that is an undoped dielectric layer.

A capacitor according to third embodiments of the inventive subject matter will now be described with reference to FIG. 5. The same components as those of the first embodiments are denoted by the same reference numerals, and repeated descriptions thereof will be briefly made or will be omitted.

FIG. 5 is a cross-sectional view illustrating a capacitor according to third embodiments of the inventive subject matter. Specifically, FIG. 5 is an enlarged view of a portion O of FIG. 2.

Referring to FIG. 5, the capacitor 30 includes a first electrode 200, a second electrode 220 and a capacitor dielectric layer 210. The capacitor dielectric layer 210 includes a lower dielectric layer 213a and an upper dielectric layer 213b.

In a capacitor according to the third embodiments of the inventive subject matter, the lower dielectric layer 213a and the upper dielectric layer 213b may be made of the same dielectric material. In addition, the lower dielectric layer 213a and the upper dielectric layer 213b may include the same impurity, i.e., the second impurity. However, the second impurity is included in the lower dielectric layer 213a and the upper dielectric layer 213b in different concentrations. The lower dielectric layer 213a and the upper dielectric layer 213b have different impurity concentrations.

The lower dielectric layer 213a and the upper dielectric layer 213b may include an oxide of a lanthanide-series element, hafnium and zirconium. In some embodiments, the lower dielectric layer 213a and the upper dielectric layer 213b may include nitride or oxynitride of a lanthanide-series element, hafnium and zirconium.

The second impurity included in the lower dielectric layer 213a and the upper dielectric layer 213b may decrease energy band gaps of the lower dielectric layer 213a and the upper dielectric layer 213b. The second impurity may include, for example, at least one of titanium (Ti), tantalum (Ta) and strontium (Sr), but not limited thereto. The second impurity may be any material that is doped into interstitial sites of the upper dielectric layer 213b and the lower dielectric layer 213a and decreases the energy band gaps of the upper dielectric layer 213b and the lower dielectric layer 213a.

A concentration of the first impurity included in the lower dielectric layer 213a may be a third impurity concentration, and a concentration of the first impurity included in the upper dielectric layer 213b may be a fourth impurity concentration.

In a capacitor according to the third embodiments of the inventive subject matter, the third impurity concentration, i.e., the impurity concentration of the lower dielectric layer 213a, is smaller than the fourth impurity concentration, i.e., the impurity concentration of the upper dielectric layer 213b.

Since the second impurity decreasing the energy band gap is included in the lower dielectric layer 213a and the upper dielectric layer 213b, the energy band gaps of both of the upper dielectric layer 213b and the lower dielectric layer 213a decrease, but the energy band gap of the upper dielectric layer 213b decreases in a greater extent than that of the lower dielectric layer 213a.

Since a larger amount of the second impurity decreasing the energy band gap is included in the upper dielectric layer 213b than in the lower dielectric layer 213a, the energy band gap of the lower dielectric layer 213a including the second impurity of the third impurity concentration is greater than that of the upper dielectric layer 213b including the second impurity of the fourth impurity concentration.

A capacitor according to fourth embodiments of the inventive subject matter will now be described with reference to FIG. 6. The same components as those of the first embodiments are denoted by the same reference numerals, and repeated descriptions thereof will be briefly made or will be omitted.

FIG. 6 is a cross-sectional view illustrating a capacitor according to fourth embodiments of the inventive subject matter. Specifically, FIG. 6 is an enlarged view of a portion O of FIG. 2.

Referring to FIG. 6, the capacitor 40 includes a first electrode 200, a second electrode 220 and a capacitor dielectric layer 210. The capacitor dielectric layer 210 includes a lower dielectric layer 214a and an upper dielectric layer 214b.

In a capacitor according to the fourth embodiments of the inventive subject matter, the lower dielectric layer 214a and the upper dielectric layer 214b may be made of the same dielectric material. In addition, the upper dielectric layer 214b may include a second impurity, but the lower dielectric layer 214a includes no impurity, so that an impurity concentration of the lower dielectric layer 214a may be substantially 0. The lower dielectric layer 214a may be an undoped dielectric layer. As the result, the lower dielectric layer 214a and the upper dielectric layer 214b may have different concentrations.

The lower dielectric layer 214a and the upper dielectric layer 214b may include one oxide of a lanthanum-series element, hafnium and zirconium. In some embodiments, the lower dielectric layer 214a and the upper dielectric layer 214b may include one nitride or oxynitride of a lanthanum-series element, hafnium and zirconium.

The second impurity included in the upper dielectric layer 214b may decrease the energy band gap of the upper dielectric layer 214b. The second impurity may include, for example, at least one of titanium (Ti), tantalum (Ta) and strontium (Sr), but not limited thereto.

Since the upper dielectric layer 214b includes the second impurity decreasing its energy band gap, the energy band gap of the upper dielectric layer 214b including the second impurity is smaller than that of the lower dielectric layer 214a that is an undoped dielectric layer.

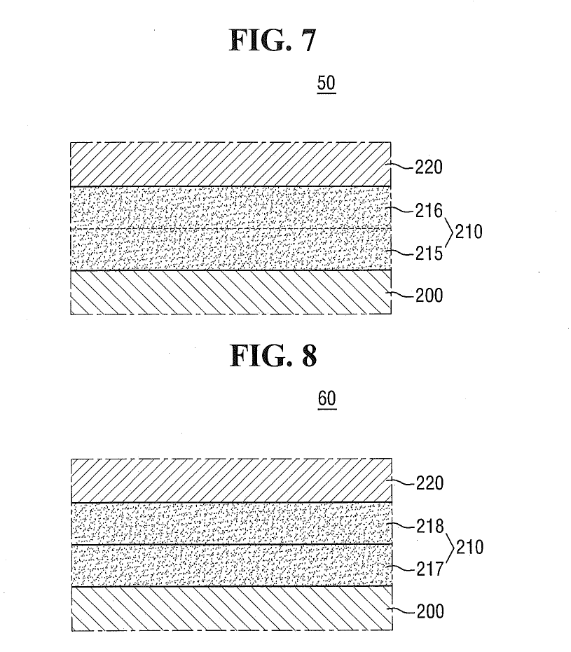

A capacitor according to fifth embodiments of the inventive subject matter will now be described with reference to FIG. 7. The same components as those of the first embodiments are denoted by the same reference numerals, and repeated descriptions thereof will be briefly made or will be omitted.

FIG. 7 is a cross-sectional view illustrating a capacitor according to fifth embodiments of the inventive subject matter. Specifically, FIG. 7 is an enlarged view of a portion O of FIG. 2.

Referring to FIG. 7, the capacitor 50 includes a first electrode 200, a second electrode 220 and a capacitor dielectric layer 210. The capacitor dielectric layer 210 includes a lower dielectric layer 215 and an upper dielectric layer 216.

In a capacitor according to the fifth embodiments of the inventive subject matter, the lower dielectric layer 215 and the upper dielectric layer 216 may be made of the same dielectric material. The lower dielectric layer 215 may include a first impurity, and the upper dielectric layer 216 may include a second impurity. The lower dielectric layer 215 and the upper dielectric layer 216 sequentially formed on the first electrode 200 may include a first impurity and a second impurity different from each other.

The lower dielectric layer 215 and the upper dielectric layer 216 may include one oxide of a lanthanum-series element, hafnium and zirconium. In some embodiments, the lower dielectric layer 215 and the upper dielectric layer 216 may include one nitride or oxynitride of a lanthanum-series element, hafnium and zirconium.

The first impurity included in the lower dielectric layer 215 may increase the energy band gap of the lower dielectric layer 215. The first impurity may include, for example, at least one of silicon (Si), aluminum (Al), hafnium (Hf) and zirconium (Zr), but not limited thereto. The second impurity included in the upper dielectric layer 216 may decrease the energy band gap of the upper dielectric layer 216. The second impurity may include, for example, at least one of titanium (Ti), tantalum (Ta) and strontium (Sr), but not limited thereto.

Since the lower dielectric layer 215 includes the first impurity increasing its energy band gap, the energy band gap of the lower dielectric layer 215 is greater than that of an undoped lower dielectric layer.

Since the upper dielectric layer 216 includes the second impurity decreasing its energy band gap, the energy band gap of the upper dielectric layer 216 is smaller than that of an undoped upper dielectric layer. Therefore, since the lower dielectric layer 215 and the upper dielectric layer 216 are made of dielectric materials having the same energy band gap, the energy band gap of the lower dielectric layer 215 including the first impurity is greater than that of the upper dielectric layer 216 including the second impurity.

In some embodiments, the upper dielectric layer 216 and the lower dielectric layer 215 are made of oxides. In a capacitor according to the fifth embodiments of the inventive subject matter, the lower dielectric layer 215 may have a chemical formula MOₓ; D₁, and the upper dielectric layer 216 may have a chemical formula MOₓ: D₂. In the lower dielectric layer 215, when M is a lanthanide-series element, the first impurity D₁ may be one of silicon (Si), aluminum (Al), hafnium (Hf) and zirconium (Zr). However, when M is one of hafnium (Hf) and zirconium (Zr), the first impurity D₁ may be one of may be one of silicon (Si) and aluminum (Al) so as not to be the same material as M, i.e., hafnium (Hf) or zirconium (Zr).

A capacitor according to sixth embodiments of the inventive subject matter will now be described with reference to FIG. 8. The same components as those of the first embodiments are denoted by the same reference numerals, and repeated descriptions thereof will be briefly made or will be omitted.

FIG. 8 is a cross-sectional view illustrating a capacitor according to sixth embodiments of the inventive subject matter. Specifically, FIG. 8 is an enlarged view of a portion O of FIG. 2.

Referring to FIG. 8, the capacitor 60 includes a first electrode 200, a second electrode 220 and a capacitor dielectric layer 210. The capacitor dielectric layer 210 includes a lower dielectric layer 217 and an upper dielectric layer 218.

In a capacitor according to the sixth embodiments of the inventive subject matter, the lower dielectric layer 217 and the upper dielectric layer 218 may be made of different dielectric materials. The lower dielectric layer 217 and the upper dielectric layer 218 may be made of different matrix materials. In addition, the lower dielectric layer 217 may include a first impurity, and the upper dielectric layer 218 may include a second impurity different from the first impurity.

The lower dielectric layer 217 and the upper dielectric layer 218 may include one oxide of a lanthanum-series element, hafnium and zirconium. In some embodiments, the lower dielectric layer 217 and the upper dielectric layer 218 may include one nitride or oxynitride of a lanthanum-series element, hafnium and zirconium.

In a capacitor according to the sixth embodiments of the inventive subject matter, an undoped lower dielectric layer has a first energy band gap, and an undoped upper dielectric layer has a second energy band gap. The first energy band gap may be greater than the second energy band gap.

The first impurity included in the lower dielectric layer 217 may be a material increasing the energy band gap of the lower dielectric layer 217, and the second impurity included in the upper dielectric layer 218 may be a material decreasing the energy band gap of the upper dielectric layer 218.

Accordingly, the lower dielectric layer 217 including the first impurity has a greater energy band gap than the undoped lower dielectric layer, and the upper dielectric layer 218 including the second impurity has a smaller energy band gap than the undoped upper dielectric layer. Therefore, the lower dielectric layer 217 including the first impurity has a greater energy band gap than the upper dielectric layer 218 including the second impurity.

In a capacitor according to the sixth embodiments of the inventive subject matter, the first impurity increasing the energy band gap is doped into the lower dielectric layer 217 having a greater energy band gap than the upper dielectric layer 218, and the second impurity decreasing the energy band gap is doped into the upper dielectric layer 218 having a smaller energy band gap than the lower dielectric layer 217, but embodiments of the inventive subject matter are not limited thereto.

The same impurity may be doped into the lower dielectric layer 217 and the upper dielectric layer 218 having a smaller energy band gap than the lower dielectric layer 217. If the first impurity increasing the energy band gap is doped, an impurity concentration of the lower dielectric layer 217 may be greater than that of the upper dielectric layer 218. If the second impurity decreasing the energy band gap is doped, an impurity concentration of the lower dielectric layer 217 may be smaller than that of the upper dielectric layer 218.

In addition, the first impurity increasing the energy band gap may be doped into the lower dielectric layer 217, and the upper dielectric layer 218 having a smaller energy band gap than the lower dielectric layer 217 may be an undoped dielectric layer.

In addition, the second impurity decreasing the energy band gap may be doped into the upper dielectric layer 218, and the lower dielectric layer 217 having a greater energy band gap than the upper dielectric layer 218 may be an undoped dielectric layer.

Hereinafter, I-V characteristic curves of capacitors according to first to sixth embodiments of the inventive subject matter will be described.

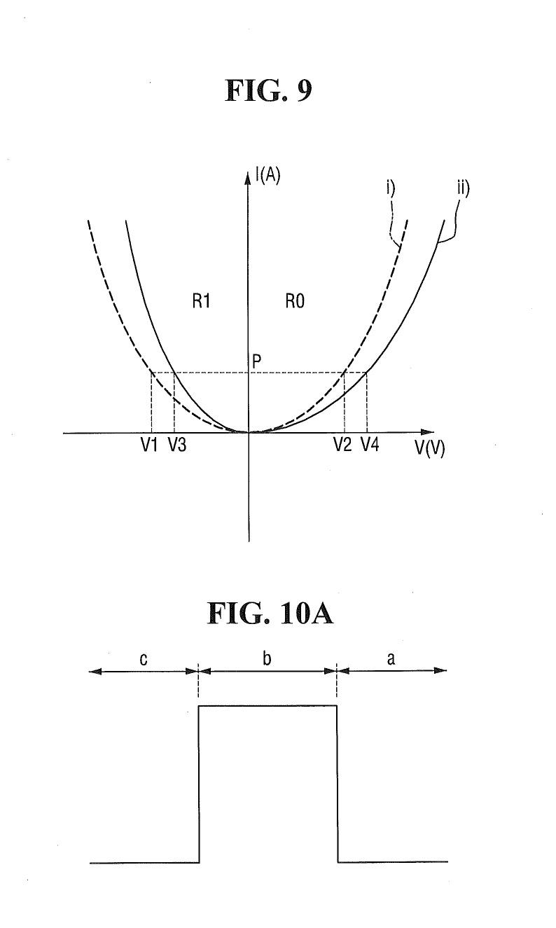

FIG. 9 illustrates I-V characteristic curves of capacitors according to some embodiments of the inventive subject matter,

In FIG. 9, the curve i) is an I-V characteristic curve of a capacitor when impurity is not doped or uniformly doped into a capacitor dielectric layer. In FIG. 9, the curve ii) is an I-V characteristic curve of a capacitor when a capacitor dielectric layer is subjected to band gap engineering by differentially doping impurity.

In FIG. 9, R0 refers to a region to which a positive voltage is applied, and R1 refers to a region to which a negative voltage is applied. In addition, the horizontal axis V indicates voltages applied to the capacitor, and the vertical axis I indicates leakage current measured when a voltage is applied.

In FIG. 9, the I-V characteristic curve of the capacitor moves from the i) curve to the ii) curve when the capacitor dielectric layer is subjected to band gap engineering.

In the R1 region, the I-V characteristic curve of the capacitor moves toward the vertical axis, and in the R0 region, the I-V characteristic curve of the capacitor moves away from the vertical axis. In other words, the absolute value of the voltage applied to generate leakage current of a value P decreases from −V1 to −V3 in the R1 region and increases from V2 to V4 in the R0 region.

In capacitors according to some embodiments of the inventive subject matter, the capacitor dielectric layer is subjected to band gap engineering, thereby increasing asymmetry of the I-V characteristic curves of the capacitors.

The asymmetry index of the I-V characteristic curve is calculated, thereby determining whether the reliability of a semiconductor device including a capacitor is improved or not. The asymmetry index is a value obtained by dividing a positive voltage applied to generate leakage current of a predetermined level by a negative voltage applied to generate leakage current of the predetermined level, which is given in the following equation:

Asym=(V_{F}@R0)/(V_{F}@R1) (1)

When the equation 1 is applied to the I-V characteristic curve of capacitor shown in FIG. 9, the asymmetry index of the ii) curve may be obtained by dividing V4 that generates the leakage current of a value P (e.g., 10 pA) in the R0 region by −V3 that generates the leakage current of the value P in the R1 region. The asymmetry index is V4/(−V3).

In a capacitor according to some embodiments of the inventive subject matter, the asymmetry index of the I-V characteristic curve of capacitor is 1.3. When the asymmetry index of the I-V characteristic curve of capacitor is greater than or equal to 1.3, the reliability of the semiconductor device including the capacitor can be improved.

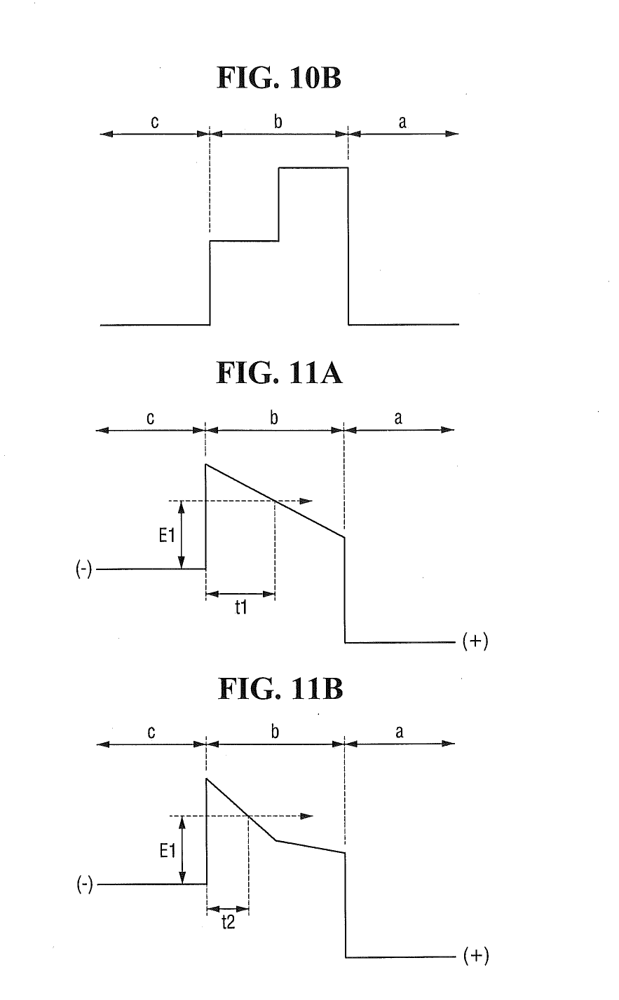

Next, changes in the energy band diagrams according to the voltages applied to the capacitors according to some embodiments of the inventive subject matter will be described with reference to FIGS. 10A to 12B.

FIGS. 10A to 12B are diagrams illustrating changes in the energy band diagrams according to the voltages applied to the capacitors according to some embodiments of the inventive subject matter. Specifically, FIGS. 10B, 11B, and 12B illustrate energy band diagrams of capacitor dielectric layers subjected to band gap engineering by doping impurity.

In FIGS. 10A to 12B, only conduction band edges of the energy band diagrams are illustrated. In FIGS. 10A to 12B, a) indicates a conduction band area of a lower electrode, b) indicates a conduction band area of a capacitor dielectric layer, and c) indicates a conduction band area of an upper electrode.

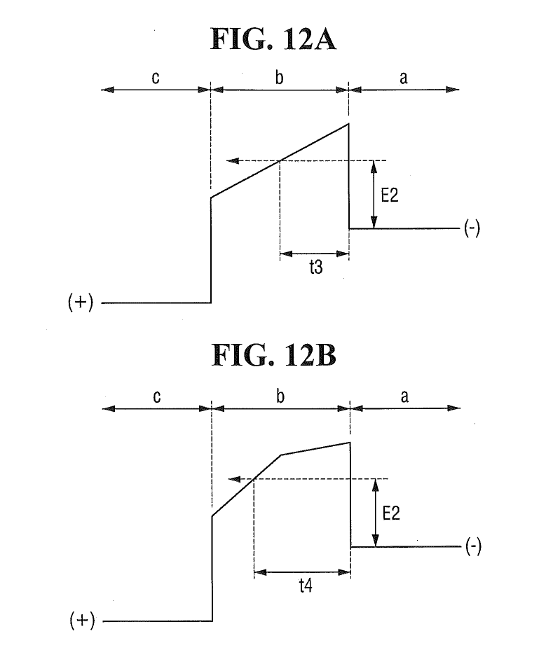

There are discontinuous spots of the energy band diagram in a boundary portion of different energy band gaps. However, for brevity of explanation, FIGS. 11B and 12B briefly illustrate the energy band diagrams as continuous.

FIGS. 10A and 10B illustrate energy band diagrams of a capacitor before a voltage is applied to the capacitor.

Referring to FIG. 10A, the energy band diagram of a capacitor not subjected to band gap engineering may be illustrated in the form of a box. However, referring to FIG. 10B, in a capacitor subjected to band gap engineering by doping impurity according to some embodiments, the energy band gap of a lower dielectric layer in contact with a lower electrode is greater than that of an upper dielectric layer, in contact with an upper electrode. Therefore, the energy band diagram of the capacitor dielectric layer may be illustrated in the form of a stairway having a step difference.

FIGS. 11A and 11B illustrate energy band diagrams of a capacitor when a negative voltage is applied to an upper electrode of the capacitor and a positive voltage is applied to a lower electrode of the capacitor. While a conduction band of the upper electrode to which the negative voltage is applied ascends, a conduction band of the lower electrode to which the positive voltage is applied descends.

Referring to FIG. 11A, in order to allow an electron at an energy level that is E1 higher than a conduction band edge of the upper electrode to move to a conduction band of the lower electrode, an energy barrier having a width t1 should be tunneled.

Referring to FIG. 11B, in order to allow an electron at an energy level that is E1 higher than a conduction band edge of the upper electrode to move to a conduction band of the lower electrode, an energy barrier having a width t2 smaller than t1 should be tunneled.

A probability of an electron passing through the energy barrier is in exponentially inverse proportion to the width of the energy barrier. In a case of a capacitor subjected to band gap engineering by doping impurity, leakage current of a predetermined level may be generated even at a low voltage applied. Thus, in the R1 region shown in FIG. 9, the absolute value of the voltage applied to generate the leakage current of the value P decreases from −V1 to −V3.

The reason of the foregoing will now be described briefly. The energy band gap of a material is generally in inverse proportion to the dielectric constant of the material. An energy band gap of a lower dielectric layer in contact with a lower electrode is greater than that of an upper dielectric layer in contact with an upper electrode, a dielectric constant of the lower dielectric layer is smaller than that of the upper dielectric layer. In addition, intensity of an electric field formed in a material is in proportion to a dielectric constant of the material. The intensity of the electric field formed in the lower dielectric layer is smaller than that of the electric field formed in the upper dielectric layer.

Since a slope of the energy band diagram is proportional to the electric field formed in the material, a slope of the upper dielectric layer having higher electric field intensity, i.e., a slope of the energy band diagram of the upper dielectric layer having a large dielectric constant is greater than that of the energy band diagram of the lower dielectric layer having a small dielectric constant.

FIGS. 12A and 12B illustrate energy band diagrams of a capacitor when a positive voltage is applied to an upper electrode of the capacitor and a negative voltage is applied to a lower electrode of the capacitor. While a conduction band of the upper electrode to which the positive voltage is applied descends, a conduction band of the lower electrode to which the negative voltage is applied ascends.

Referring to FIG. 12A, in order to allow an electron at an energy level that is E2 higher than a conduction band edge of the lower electrode to move to a conduction band of the upper electrode, an energy barrier having a width t3 should be tunneled.

Referring to FIG. 12B, in order to allow an electron at an energy level that is E2 higher than a conduction band edge of the lower electrode to move to a conduction band of the upper electrode, an energy barrier having a width t4 smaller than t3 should be tunneled.

In a case of a capacitor subjected to band gap engineering by doping impurity, leakage current of a predetermined level is generated at a high voltage applied. Thus, in the R0 region shown in FIG. 9, the absolute value of the voltage applied to generate the leakage current of the value P increases from V2 to V4.

Referring to FIGS. 9 to 12B, when a capacitor dielectric layer is subjected to band gap engineering by doping impurity, the absolute value of a voltage applied to generate leakage current decreases in the R1 region and increases in the R0 region. Accordingly, the reliability of the semiconductor device including the capacitor can be improved.

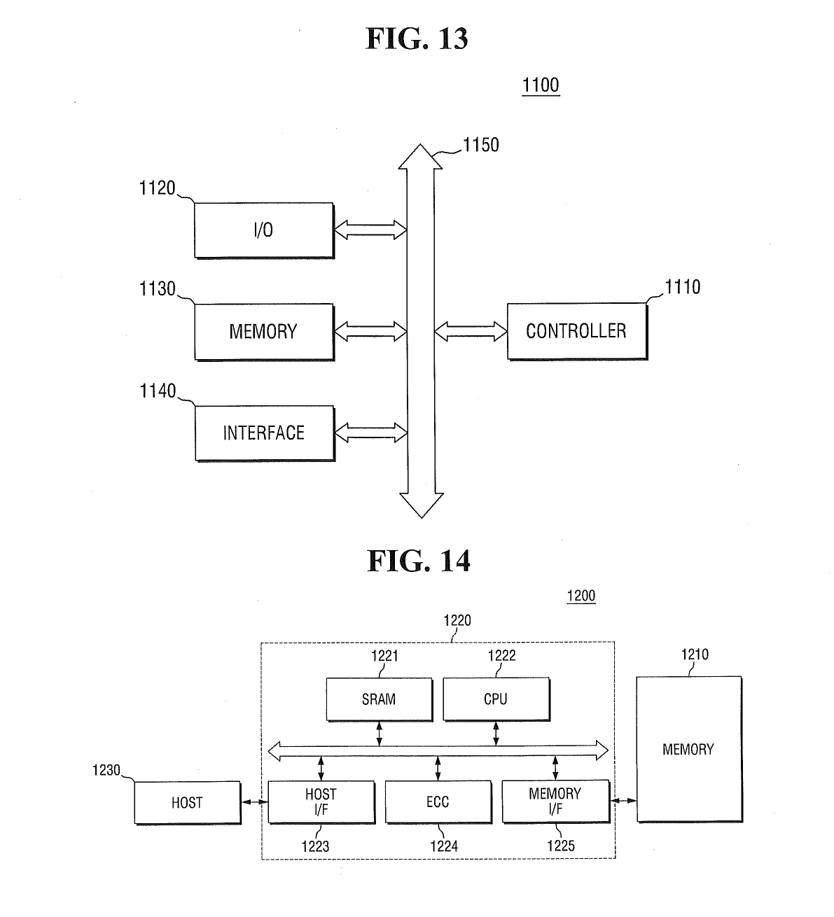

FIG. 13 is a block diagram illustrating an exemplary electronic system including semiconductor devices having capacitors according to some embodiments of the inventive subject matter.

Referring to FIG. 13, the electronic system 1100 according to some embodiments of the inventive subject matter may include a controller 1110, an input/output (I/O) device 1120, a memory 1130, an interface 1140 and a bus 1150. The controller 1110, the I/O device 1120, the memory 1130 and/or the interface 1140 may be connected to each other through the bus 1150. The bus 1150 may correspond to a path through which data moves.

The controller 1110 may include at least one of a microprocessor, a digital signal processor, a microcontroller, and logic devices capable of performing similar functions to those performed by these devices. The I/O device 1120 may include a keypad, a keyboard, a display device, and the like. The memory 1130 may store data and/or instructions. The memory 1130 may include semiconductor devices according to some embodiments of the inventive subject matter. For example, the memory 1130 may include a DRAM. The interface 1140 may transmit/receive data to/from a communication network. The interface 1140 may be wired or wireless. For example, the interface 1140 may include an antenna or a wired/wireless transceiver.

The electronic system 1100 may be applied to a personal digital assistant (PDA), a portable computer, a web tablet, a wireless phone, a mobile phone, a digital music player, a memory card, or any type of electronic device capable of transmitting and/or receiving information in a wireless environment.

FIG. 14 is a block diagram illustrating an exemplary memory card including semiconductor devices having capacitors according to some embodiments of the inventive subject matter.

Referring to FIG. 14, the memory 1210 including the semiconductor devices according to various embodiments of the inventive subject matter may be employed to a memory card 1200. The memory card 1200 may include a memory controller 1220 controlling data exchange between a host 1230 and a memory 1210. A static random access memory (SRAM) 1221 may be used as an operating memory of a central processing unit 1222. A host interface 1223 may include a protocol for exchanging data by allowing the host 1230 to be connected to the memory card 1200. An error correction code (ECC) 1224 may detect an error from data read from the memory 1210 to then correct the detected error. A memory interface 1225 may interface with the memory 1210. The central processing unit 1222 may perform the overall control operation associated with the data exchange of the memory controller 1220.

While the inventive subject matter has been particularly shown and described with reference to exemplary embodiments thereof, it will be understood by those of ordinary skill in the art that various changes in form and details may be made therein without departing from the spirit and scope of the inventive subject matter as defined by the following claims. It is therefore desired that the present embodiments be considered in all respects as illustrative and not restrictive, reference being made to the appended claims rather than the foregoing description to indicate the scope of the invention.

What is claimed is:

1. A capacitor comprising:
a first electrode;
a first dielectric layer on the first electrode;
a second dielectric layer on the first dielectric layer, wherein the first and second dielectric layers comprise the same dielectric material with different concentration of an impurity therein; and
a second electrode formed on the second dielectric layer.

2. The capacitor of claim 1, wherein the first dielectric layer has a greater energy band gap than the second dielectric layer.

3. The capacitor of claim 1, wherein the first dielectric layer has a greater concentration of an energy band gap increasing impurity than the second dielectric layer.

4. The capacitor of claim 3, wherein the energy band gap increasing impurity comprises at least one of silicon (Si), aluminum (Al), hafnium (Hf) and zirconium (Zr).

5. The capacitor of claim 3, wherein the second dielectric layer is undoped with the energy band gap increasing impurity.

6. The capacitor of claim 1, wherein the second dielectric layer has a greater concentration of an energy band gap decreasing impurity than the first dielectric layer.

7. The capacitor of claim 6, wherein the energy band gap decreasing impurity comprises at least one of titanium (Ti), tantalum (Ta) and strontium (Sr).

8. The capacitor of claim 6, wherein the first dielectric layer is undoped with the energy band gap decreasing impurity.

9. A capacitor comprising:
a first electrode;
a first dielectric layer on the first electrode and comprising a first impurity;
a second dielectric layer on the first dielectric layer and comprising a second impurity different from the first impurity; and
a second electrode formed on the second dielectric layer.

10. The capacitor of claim 9, wherein the first dielectric layer and the second dielectric layer comprise the same dielectric material, wherein the first impurity increases an energy band gap of the first dielectric layer, and wherein the second impurity decreases an energy band gap of the second dielectric layer.

11. The capacitor of claim 10, wherein the first impurity comprises at least one of silicon (Si), aluminum (Al), hafnium (Hf) and zirconium (Zr), and wherein the second impurity comprises at least one of titanium (Ti), tantalum (Ta) and strontium (Sr).

12. The capacitor of claim 9, wherein the first dielectric layer has a first energy band gap, wherein the second dielectric layer has a second energy band gap, and wherein the first energy band gap is greater than the second energy band gap.

13. The capacitor of claim 12, wherein the first impurity increases the energy band gap of the first dielectric layer, and wherein the second impurity decreases the energy band gap of the second dielectric layer.

14. A memory device comprising:
a substrate; and
a plurality of memory cells on the substrate, each of the memory cells comprising a data storage capacitor comprising multiple dielectric layers with different energy band gaps.

15. The memory device of claim 14, wherein each data storage capacitor comprises:
a first electrode;
a first dielectric layer on the first electrode;
a second dielectric layer on the first dielectric layer comprising the same dielectric material as the first dielectric layer and a different concentration of an impurity than the first dielectric layer; and
a second electrode on the second dielectric layer.

16. The memory device of claim 15, wherein the first dielectric layer has a greater concentration of an energy band gap increasing impurity than the second dielectric layer.

17. The memory device of claim 16, wherein the second dielectric layer is undoped with the energy band gap increasing impurity.

18. The memory device of claim 15, wherein the second dielectric layer has a greater concentration of an energy band gap decreasing impurity than the first dielectric layer.

19. The memory device of claim 18, wherein the first dielectric layer is undoped with the energy band gap decreasing impurity.

20. The memory device of claim 14, wherein each data storage capacitor comprises:
a first electrode;
a first dielectric layer on the first electrode and comprising a first impurity;
a second dielectric layer on the first dielectric layer and comprising a second impurity different from the first impurity; and
a second electrode formed on the second dielectric layer.
